(19) United States
(12) Patent Application Publication
(10) Pub. No.: US 2020/0321872 A1
(43) Pub. Date: Oct. 8, 2020

(54) PHASE MULTIPLIERS IN POWER CONVERTERS

(71) Applicant: Alpha and Omega Semiconductor (Cayman) Limited, Grand Cayman (KY)

(72) Inventor: Prabal Upadhyaya, San Jose, CA (US)

(21) Appl. No.: 16/374,421

(22) Filed: Apr. 3, 2019

(51) Int. Cl. H02M 3/158; H02M 3/157; H03L 7/081; H02M 1/08

(52) U.S. Cl. CPC H02M 3/1584; H02M 3/157; H02M 2001/0009; H02M 1/08; H02M 2003/1586; H03L 7/0814

(57) ABSTRACT

Apparatus and associated methods relate to copying a pulse-width-modulated (PWM) signal PWMᵢₙ to N-1 delay controllers to form N-1 time-interleaved PWM signals. In an illustrative example, each of the N-1 delay controllers may set and reset a corresponding latch to form leading and/or trailing edges of a corresponding generated PWM signal (PWM₂ to PWM_{N}) in response to a copied PWM signal and/or a phase-shifted clock. In some examples, the delay controller may fine tune the pulse width of any of the generated PWM signals (PWM₂ to PWM_{N}) to correct phase current balance supplied to a load. The phase multiplier may advantageously split one PWM signal supplied by a PWM controller, for example, into multiple interleaved PWM phase signals without expanding the number of PWM signal pins on the PWM controller.

### TECHNICAL FIELD

Various embodiments relate generally to multi-phase power conversion.

### BACKGROUND

Electronic devices, which may also be referred to as loads, receive power from a variety of electrical power sources. For example, some power sources may couple to a load device at a wall outlet (e.g., from a mains source) or may couple more directly to various local and/or portable sources (e.g., batteries, renewable energy sources, generators). Some load devices, such as central processing units (CPU) and graphics processors (GPU) continue to develop higher input current requirements while demanding tight voltage regulation and/or high efficiency from the power source.

In some electronic devices, the source voltage supply (e.g., battery input, rectified mains supply, intermediate DC supply) may be converted to a load compatible voltage by various voltage conversion circuits. Switch-mode power supplies have gained popularity as voltage conversion circuits due to their high efficiency and therefore are often used to supply a variety of electronic loads.

Switch-mode power supplies convert voltages using switching devices that turn on with very low resistance and turn off with very high resistance. Switch-mode power supplies may charge an output inductor during a period of time and may release part or all of the inductor energy during a subsequent period of time. The output energy may be delivered to a bank of output capacitors, which provide the filtering to produce a DC output voltage. In buck-derived switch-mode power supplies, the output voltage, in a steady state, may be approximately the input voltage times a duty cycle, where the duty cycle is the duration of the on-time of a pass switch divided by the total on-time and off-time of the pass switch for one switching cycle.

### SUMMARY

Apparatus and associated methods relate to copying a pulse-width-modulated (PWM) signal PWMᵢₙ to N-1 delay controllers to form N-1 time-interleaved PWM signals. In an illustrative example, each of the N-1 delay controllers may set and reset a corresponding latch to form leading and/or trailing edges of a corresponding generated PWM signal (PWM₂ to PWM_{N}) in response to a copied PWM signal and/or a phase-shifted clock. In some examples, the delay controller may fine tune the pulse width of any of the generated PWM signals (PWM₂ to PWM_{N}) to correct phase current balance supplied to a load. The phase multiplier may advantageously split one PWM signal supplied by a PWM controller, for example, into multiple interleaved PWM phase signals without expanding the number of PWM signal pins on the PWM controller.

Some apparatus and associated methods relate to adjusting a duty cycle associated with each of N-1 time-interleaved pulse-width-modulated (PWM) slave signals to cause N-1 respective slave current signals to responsively match a master current signal associated with a master PWM signal PWM1. In an illustrative example, each of the N-1 slave current signals may be determined using an analog-to-digital converter (ADC) configured to sample the master current signal and the N-1 slave current signals. In some embodiments, the ADC may collect a plurality of samples from a selected one of the current signals before selecting a different one of the current signals according, for example, to a round robin selection pattern. A moving average, for example, may be determined based upon the current signal samples. Duty cycles of each of the slave current signals may be adjusted to advantageously balance phase currents based on the current signal moving averages.

Various embodiments may achieve one or more advantages. For example, a legacy 8-phase PWM controller may be expanded to support up to 32 phases by using eight 4-channel phase multipliers without adding more pins to the PWM controller. Thus, with available pins, a PWM controller may support more interleaved phases, for example. In some embodiments, the package dimension of the PWM controller may be advantageously decreased or kept the same. For example, to support 8 phases, a PWM controller having two PWM pins may be used with two 4-channel phase multipliers, rather than using a PWM controller having eight PWM pins. Thus, the package dimension of the PWM controller may be advantageously decreased. In some embodiments, by using the phase multipliers, the same PWM controller may be extended to serve increasing current demands of central processing units (CPUs) and/or graphics processing units (GPUs). In some embodiments, the temperature effect of the power stages may be taken into consideration by using smart power stages. In some embodiments, the accuracy of the current monitoring signal may be kept by directly feeding a master current monitoring signal of a smart power stage to the PWM controller. In some embodiments, the pulse width of each generated PWM signals may be fine-tuned or adjusted by using a phase current control circuit ISHARE.

Further, some embodiments may advantageously provide for enhanced current balance among phases while, for example, increasing the ratio of interleaved phases-to-PWM controller pin count. With improved current balance and capability to expand to implement more phases, cost, size, weight, and reliability advantages may result from the reduced dependency on, for example, bulk and filtering capacitance.

The details of various embodiments are set forth in the accompanying drawings and the description below. Other features and advantages will be apparent from the description and drawings, and from the claims.

### BRIEF DESCRIPTION OF THE DRAWINGS

FIG. 1 depicts a power converter implemented with an exemplary phase multiplier.

FIG. 2 depicts an architecture of the exemplary phase multiplier.

FIG. 3 depicts timing diagrams of exemplary signals received and generated by the phase multiplier.

FIG. 4 depicts a flow chart of an exemplary method to generate multiple PMW signals with different phases.

FIG. 5A depicts an architecture of an exemplary phase multiplier adapted to balance phase currents.

FIG. 5B depicts an architecture of an exemplary phase current control circuit in the phase multiplier of FIG. 5A.

FIG. 5C depicts timing diagrams of a system clock signal, exemplary generated pulse-width-modulated (PWM) signals and phase currents.

FIG. 6 depicts a flow chart of an exemplary method to adjust duty cycles of the generated PWM signals to balance phase currents.

Like reference symbols in the various drawings indicate like elements.

### DETAILED DESCRIPTION OF ILLUSTRATIVE EMBODIMENTS

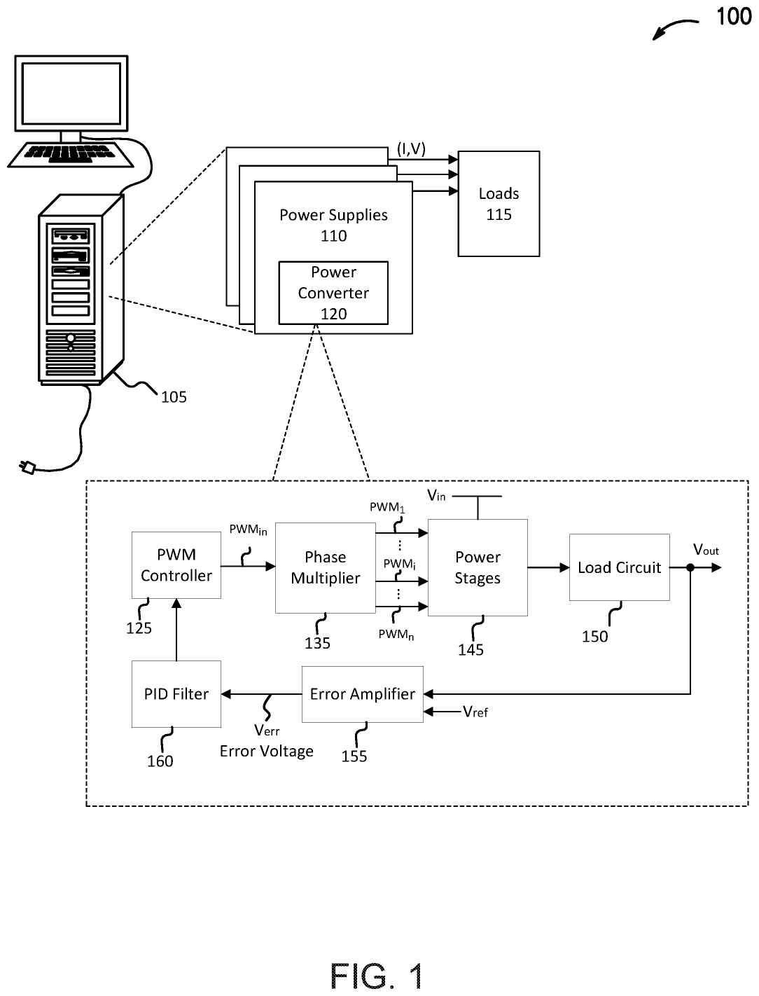

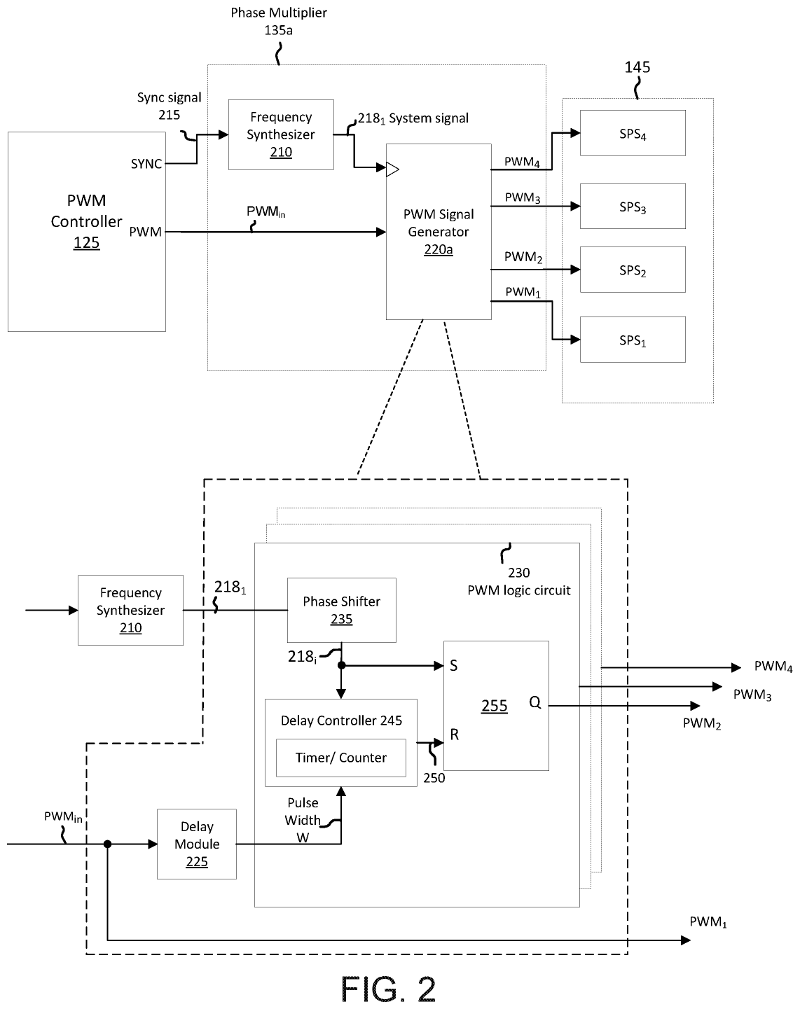

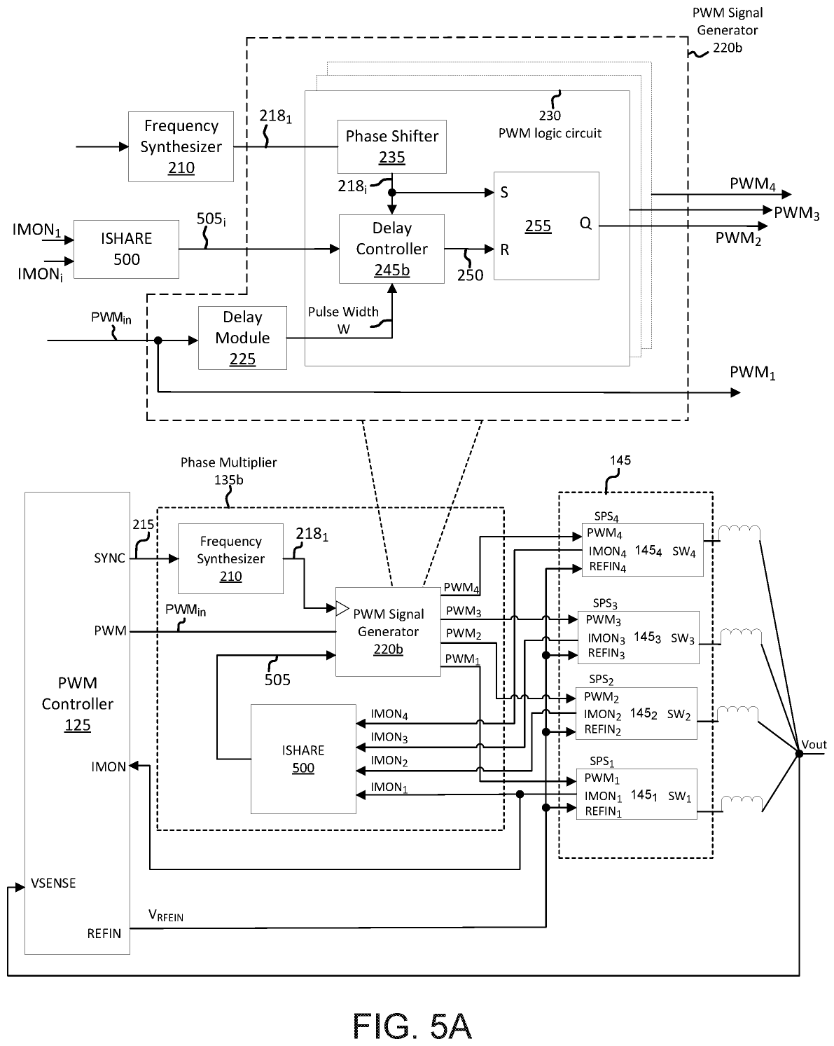

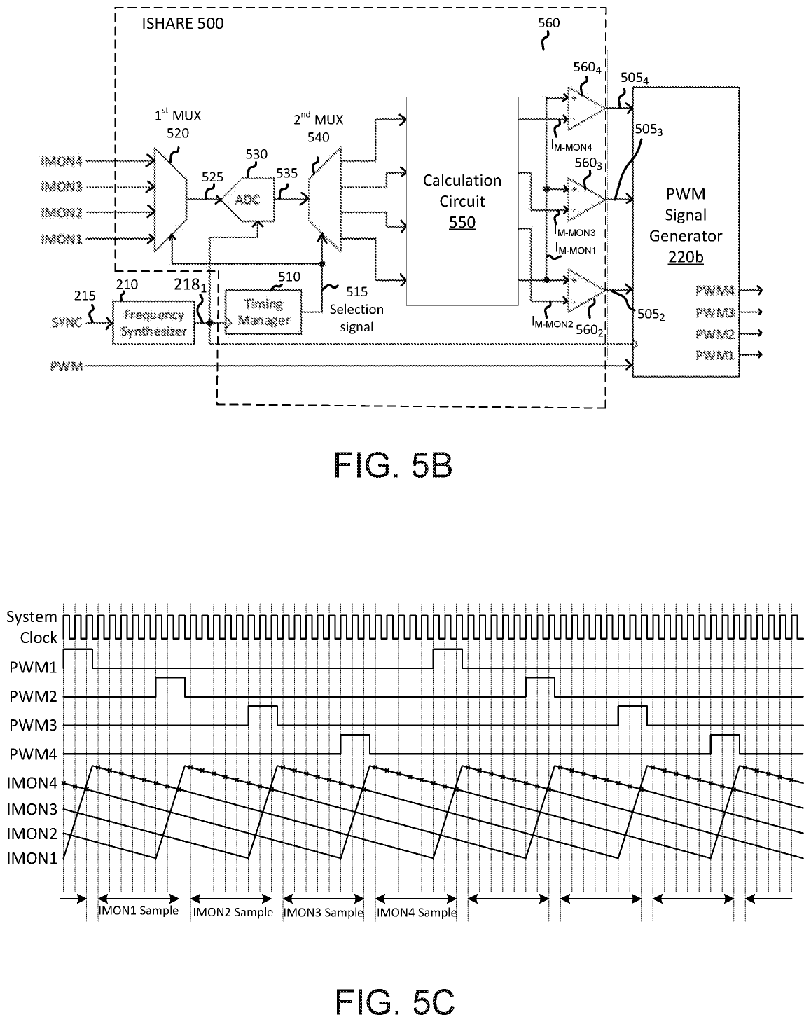

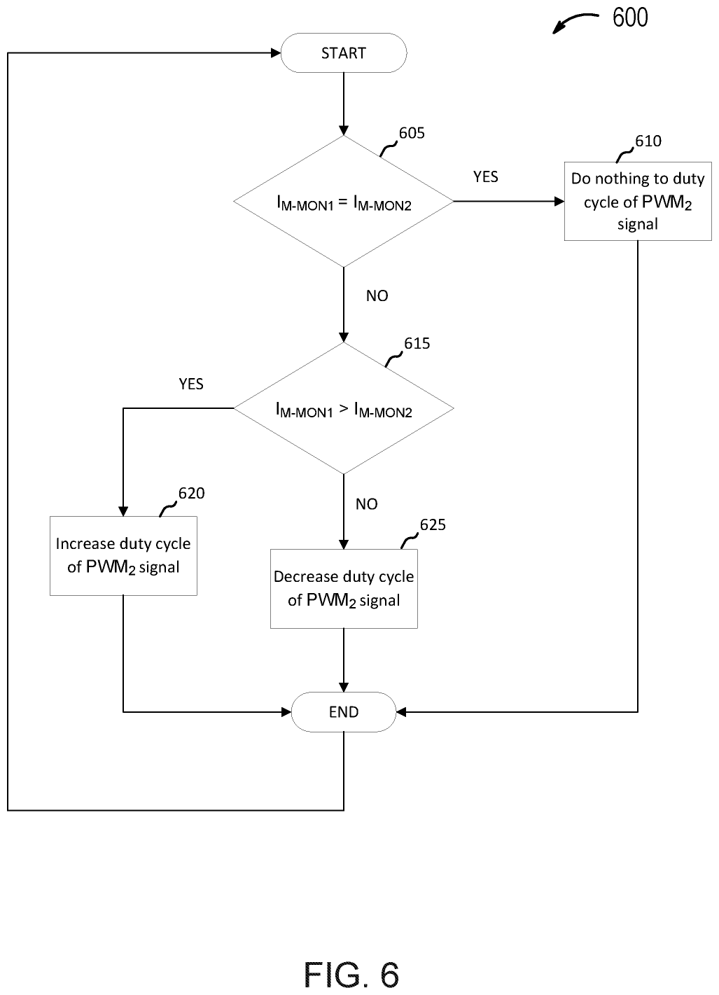

To aid understanding, this document is organized as follows. First, a power converter having an exemplary phase multiplier that is configured to generate several interleaved pulse-width-modulated (PWM) signals in response to an incoming pulse-width-modulated (PWM) signal is briefly introduced with reference to FIG. 1. Second, with reference to FIGS. 2-4, the discussion turns to exemplary embodiments that illustrate the architecture of the phase multiplier. Then, with reference to FIGS. 5A-5C, further explanatory discussion is presented to explain a circuit to generate PWM signals with balanced currents among the interleaved phases. Finally, with reference to FIG. 6, further explanatory discussion is presented to explain a method to modulate duty cycles of the generated PWM signals so as to balance phase currents.

DC-to-DC voltage conversion is often performed by switch-mode voltage regulators, also referred to as voltage converters or point-of-load (POL) regulators/converters. One type of DC-to-DC converter, called a buck or step-down regulator, may convert a higher voltage (e.g., 12V) to a lower value as required by one or more load devices. More generally, voltage regulators and current regulators are commonly referred to as power converters, and as used herein, the term power converter is meant to encompass such devices.

FIG. 1 depicts a power converter implemented with an exemplary phase multiplier. In this depicted example, a system 100 includes a powered load system 105. The powered load system 105 includes one or more interleaved power supplies 110 implemented in the computer 105 supplying one or more loads 115. In some examples, the loads 115 may be specified to operate at an input voltage with limited voltage perturbations. The power supplies 110 include a power converter 120. The power converter 120 regulates currents and/or voltages supplied into the loads 115. The power converter 120 is configured to dynamically modulate the frequency of a switch signal to achieve a fast transient response. More specifically, the power converter 120 includes a pulse width modulator (PWM) controller 125 controlling the input to associated power switches. In an illustrative example, the PWM controller 125 generates one or more incoming pulse-width-modulated signals (e.g., PWMᵢₙ) with a commanded duty ratio at the frequency of f_{sw}. The power converter 120 also includes a phase multiplier 135. As will be described in more detail with reference to FIG. 2, the power converter 120 may advantageously support well balanced, high numbers of phases by employing an exemplary phase multiplier 135 configured to generate N-1 phase signals (PWM₂ . . . PWMₙ) from the single PWMᵢₙ signal from the PWM controller 125.

The phase multiplier 135 receives the incoming pulse-width-modulated signal (e.g., PWMᵢₙ) and generates N-1 pulse-width-modulated signals based on the PWMᵢₙ signal. The generated N-1 pulse-width-modulated signals share the same frequency with the PWMᵢₙ. The N pulse-width-modulated signals have different phases. In the depicted figure, one of the N pulse-width-modulated signals may have the same phase information with the incoming pulse-width-modulated signal PWMᵢₙ, the rest of the N pulse-width-modulated signals may have a predetermined phase shift degree relative to the incoming pulse-width-modulated (PWM) signal PWMᵢₙ. The predetermined phase shift degree may be (i-1)*360°/N. i is the i^{th} generated pulse-width-modulated signal. For example, a phase multiplier may output four PWM signals PWM₁, PWM₂, PWM₃, and PWM₄. The four PWM signals PWM₁, PWM₂, PWM₃, and PWM₄ have the same frequency with the incoming pulse-width-modulated signal PWMᵢₙ. The four PWM signals PWM₁, PWM₂, PWM₃, and PWM₄ have different phase information. PWM₁ may have the same phase with the PWMᵢₙ, PWM₂ may have a 90-degree phase shift compared to the PWMᵢₙ, PWM₃ may have a 180-degree phase shift compared to the PWMᵢₙ and PWM₄ may have a 270-degree phase shift compared to the PWMᵢₙ.

The phase multiplier 135 can split one incoming PWM signal (e.g., PWMᵢₙ) into multiple outgoing PWM signals to support high phase count. By introducing the phase multiplier 135, although the PWM controller may have limited PWM pin numbers, N times PWM signals may be available for power stages to be operated at peak efficiency. Thus, for example an 8-phase controller along with eight 4-channel phase multipliers may be used to support up to 32 phases, which may allow the same PWM controller to serve both central processing unit (CPU) and graphics processing unit (GPU).

The power converter 120 also includes N power stages 145 connected with the phase multiplier 135 in series. Each of the N power stages 145 receives one of the generated PWM signals and provides power to a load circuit 150. In some embodiments, each of the N power stages 145 may include many power transistors. The power converter may switch a pair of power transistors to produce a square-wave at the transistors' common node SW (not shown). The produced square-wave may be smoothed out using the load circuit 150 to produce a desired voltage Vₒᵤₜ. In some embodiments, each of the N power stages 145 may be a smart power stage (SPS). An SPS may refer to a power stage having integrated high accuracy current and temperature monitors that can feed back signals to the PWM controller 125 and/or phase multiplier 135 to complete a multiphase DC-DC system.

The power converter 120 also includes an error amplifier 155. The error amplifier 155 receives the output voltage signal Vₒᵤₜ and a reference voltage signal V_{ref} to generate an error signal Vₑᵣᵣ. The error signal may be received by proportional-integral-derivative (PID)) filter 160. The PID filter 160, the PWM controller 125, and the phase multiplier 135 may be configured to control the duty cycle of the output of the square-wave Vₒᵤₜ.

FIG. 2 depicts an architecture of an exemplary phase multiplier. In this depicted example, the PWM controller 125 generates a sync clock signal 215. The sync clock signal 215 may have a frequency f_{sync} that is several times the frequency f_{sw} of the incoming PWM signal PWMᵢₙ. For example, the frequency of the sync clock signal 215 may be 32 times or at least 64 times or more of the frequency f_{sw} of the PWMᵢₙ. The sync clock signal 215 and the incoming PWM signal PWMᵢₙ are received by the phase multiplier 135a to output N PWM signals (e.g., PWM₁, PWM₂, PWM₃, and PWM₄). The N PWM signals are received by N power stages 145. In some embodiments, the N power stages 145 may be smart power stages.

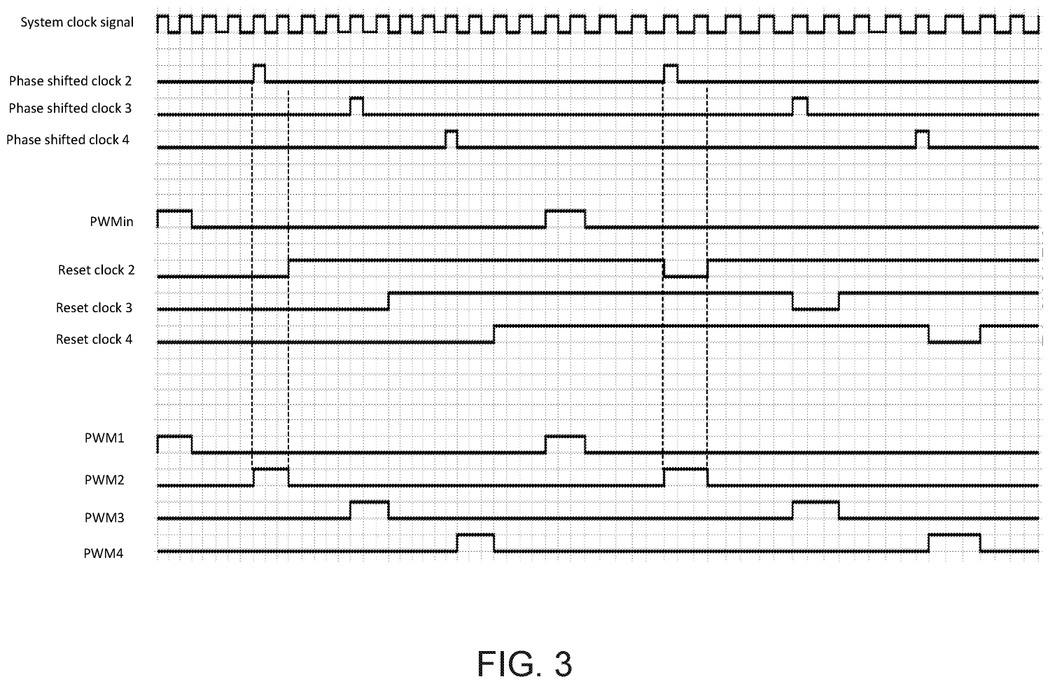

The phase multiplier 135a includes a frequency synthesizer 210. The frequency synthesizer 210 is configured to receive the sync clock signal 215 to generate a system clock signal 218₁. The system clock signal 218₁ may have a frequency f_{sys} that is M times the frequency f_{sw} of the incoming PWM signal PWMᵢₙ. For example, the frequency of the system clock signal 218₁ may be 32 times or at least 64 times or more of the frequency f_{sw} of the PWMᵢₙ. Although, in this depicted example, the frequency synthesizer 210 receives a sync clock signal 215 from a SYNC pin of the PWM controller 125, in some embodiments, the frequency synthesizer 210 may receive other signals (e.g., the incoming PWM signal PWMᵢₙ) to generate the system clock signal 218₁. Exemplary timing diagrams of the system clock 218₁, and the incoming PWM signal PWMᵢₙ are shown in FIG. 3.

The phase multiplier 135 also includes a PWM signal generator 220a. The PWM signal generator 220a receives the system clock signal 218₁ and the incoming PWM signal PWMᵢₙ to generate N-1 PWN signals (e.g., PWM₂, PWM₃, and PWM₄). Each of the generated N-1 PWM signals will be received by a corresponding SPS (e.g., SPS₁, SPS₂, SPS₃, and SPS₄). The incoming PWM signal PWMᵢₙ will be directly used as a first PWM signal PWM₁.

The PWM signal generator 220a, configured to generate N-1 PWM signals, includes a delay module 225. The delay module 225 receives the incoming PWM signal PWMᵢₙ and copies the pulse width W of the incoming signal PWMᵢₙ. The copied pulse width W will be received by N-1 slices of PWM logic circuit 230. In some embodiments, the delay module 255 may include a delay locked loop (DLL) to copy the pulse width W.

Each PWM logic circuit 230 of the N-1 slices of PWM logic circuit includes a phase shifter 235. The phase shifter 235 receives the system clock signal 218₁ to generate a phase-shifted clock signal 218ᵢ. Each phase-shifted clock signal 218ᵢ has a predetermined shifted degree. The predetermined shifted degree may be (i-1)*360/N. i is the i^{th} PWM signal PWMᵢ, N is the total number of generated PWM signals. For example, when N=4, a phase-shifted clock signal 218₂ is used to generate a second PWM signal PWM₂. The second PWM signal PWM₂ may have a 90-degree phase shifting compared to the system clock signal 218₁.

The phase-shifted clock signal 218ᵢ and the pulse width W of the incoming signal PWMᵢₙ are received by a delay controller 245. The delay controller 245 will generate a reset signal 250 in response to the phase-shifted clock signal 218ᵢ and the pulse width W. For example, the rising edge of the phase-shifted clock signal 218ᵢ may trigger the delay controller 245 to initiate a delay timer. When the delay timer expires, the delay controller 245 may generate a reset signal (e.g., digital 1) 250. For example, the pulse width W may have 2.5 clock cycles of the system clock 218₁. Thus, after 2.5 clock cycles of the system clock 218₁ (e.g., delay timer expires), the delay controller 245 generates the logic high reset signal 250.

Each PWM logic circuit 230 also includes a set-reset (SR) latch 255. The phase-shifted clock signal 218ᵢ is used to set the SR latch 255, and the reset signal 250 is used to reset the SR latch 255. The SR latch 255 generates a corresponding PWM signal in response to the phase-shifted clock signal 218ᵢ and the reset signal 250. The rising edge of the corresponding generated PWM signal happens at the rising edge of the phase-shifted clock signal 218ᵢ. The falling edge of the corresponding generated PWM signal may happen in response to the delay timer expiration.

FIG. 3 depicts an exemplary timing diagram of signals received and generated by the phase multiplier. In this depicted example, the frequency f_{sys} of the system clock signal 218_{1 is} 32 times (e.g., M=32) of the frequency of the incoming PWM signal PWMᵢₙ, and the phase multiplier 135 is configured to generate four PWM signals (e.g., N=4). Three phase-shifted clock signals (phase-shifted clock 2, 3, 4) generated by the phase shifter 235 have the same pulse width with the system clock signal 218₁ and have the same frequency with the incoming PWM signal PWMᵢₙ. Each of the three phase-shifted clock signals may be shifted by a predetermined degree. For an i^{th} phase-shifted clock signal, the shifted degree is (i-1)*360/N. As the incoming PWM signal PWMᵢₙ is directly used as a first output PWM signal PWM₁, a phase generator only needs to generate PWM₂, PWM₃, and PWM₄. Thus, only three phase-shifted clock signals (e.g., 218ᵢ) may be needed, i≥2. As shown in the timing diagram, a third phase-shifted clock has a 90-degree phase shifting relative to the second phase-shifted clock. A fourth phase-shifted clock has a 90-degree phase shifting relative to the third phase-shifted clock. Reset clock signal may be triggered by a corresponding phase-shifted clocks signal and expire when delay timer expires. When the rising edge of the phase-shifted clock (e.g., a second phase-shifted clock) happens, a delay timer may be triggered. The delay timer may be set to have a time period that is equal to the corresponding time period of the pulse width W of the incoming PWM signal PWMᵢₙ. Reset clock signals may be initialized to 0. When the delay timer expires, the delay controller may generate a digital high reset signal (e.g., digital 1). A corresponding phase-shifted clock (e.g., the second phase-shifted clock signal) and a corresponding reset clock signal (e.g., a second reset clock signal) may be received by a set-reset latch (e.g., the SR latch 255) to generate a corresponding PWM signal (e.g., PWM₂). The generated four PWM signals have the same frequency with the incoming PWM signal PWMᵢₙ. PWM₁ has the same phase with the PWMᵢₙ, each of the rest of the generated PWM signals has a corresponding predetermined phase shift compared to the incoming PWM signal PWMᵢₙ.

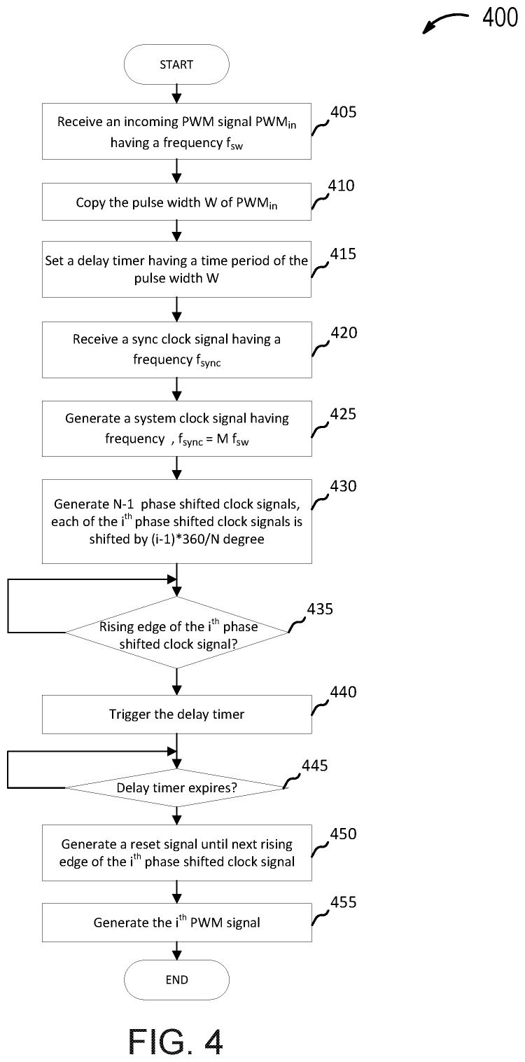

FIG. 4 depicts a flow chart of an exemplary method to generate multiple PMW signals with different phases. A method 400 includes, at 405, receiving an incoming PWM signal PWMᵢₙ, the frequency of incoming PWM signal PWMᵢₙ is f_{sw}. At 410, a delay module (e.g., delay module 225) copies the pulse width W of the incoming PWM signal PWMᵢₙ. At 415, the copied pulse width W is used to set a delay timer. The delay timer has a time period of the copied pulse with W.

At 420 and 425, a frequency synthesizer (e.g., the frequency synthesizer 210) receives a sync clock signal (e.g., the sync clock signal 215) to generate a system clock signal (e.g., the system clock signal 218₁). The frequency f_{sys} of the system clock signal is M times the frequency f_{sw} of the incoming PWM signal PWMᵢₙ. At 430, the system clock signal 218₁ is then received by N-1 phase shifters. Each phase shifter receives the system clock signal 218₁ and generates a corresponding phase-shifted clock signal 218ᵢ with a predetermined (i-1)*360/N, N≥i≥2. In some embodiments, the frequency synthesizer 210 may receive other signals (e.g., the incoming PWM signal PWMᵢₙ) to generate the system clock signal 218₁.

At 435, the delay controller 245 keeps monitoring whether the rising edge of the i^{th} phase clock signal happens. If the rising edge of the i^{th} phase clock signal happens, then the delay controller 245 triggers the delay timer to start counting on a time period of the copied pulse with W. At 445, the delay controller 245 keeps monitoring whether the delay timer expires. If the delay timer expired, then, at 450, the delay controller 245 generates a digital high reset signal (e.g., the reset signal 250). The corresponding phase-shifted clock signal 218ᵢ and the corresponding reset signal 250 are received by an SR latch to generate an i^{th} PWM signal PWMᵢ. The incoming PWM signal PWMᵢₙ is used directly as a first PWM signal. Following this method, N-1 PWM signals may be controllably generated in accordance with various embodiments described herein.

FIG. 5A depicts an architecture of an exemplary phase multiplier adapted to balance phase currents. In this depicted example, the N power stages 145 are smart power stages (e.g., SPS₁, SPS₂, SPS₃, and SPS₄). The phase multiplier 135b generates N PWM signals (e.g., PWM₁, PWM₂, PWM₃, and PWM₄). The N PWM signals are received by the N smart power stages. Each smart power stage of the N smart phase stages 145 receives a corresponding PWM signal and generates a corresponding current monitor output signal I_{MONx} referenced to a reference voltage V_{REFIN}. The reference voltage V_{REFIN} may be a direct voltage supplied by an external source. In this depicted example, the reference voltage V_{REFIN} is supplied by the PWM controller 125.

The N current monitor output signals I_{MONx} (e.g., I_{MON1}, I_{MON2}, I_{MON3}, I_{MON4}) include a master current monitor output signal (e.g., I_{MON1}), and the rest of the N current monitor output signals I_{MONi} (e.g., I_{MON2}, I_{MON3}, I_{MON4}) are slave current monitor output signals. The master current monitor output signal is directly reported back to the PWM controller 125 to maintain the accuracy of the I_{MON} reported by an SPS.

All current monitor output signal are returned back to the phase multiplier 135. More specifically, the phase multiplier 135 also includes a phase current control circuit ISHARE 500. All current monitor output signals I_{MONx} are returned back to the ISHARE 500. The differences between each of the slave current monitor output signals I_{MONi} and the master current monitor output signal I_{MONi} may be calculated. The calculated differences 505 may be reported to the PWM signal generator 220 to change the duty cycle of a corresponding PWM signal. An exemplary method to fine tune the duty cycle of a corresponding PWM signal is described in further detail with reference to FIG. 6.

FIG. 5B depicts an architecture of an exemplary phase current control circuit (ISHARE) in the phase multiplier of FIG. 5A. The phase current control circuit (ISHARE) 500 includes a timing manager 510. The timing manager 510 is triggered by the system clock signal 218₁ to generate a selection signal 515.

ISHARE 500 also includes a first four-input multiplexer 520. The first four-input multiplexer 520 receives the four current monitor output signals (e.g., I_{MON1}, I_{MON2}, I_{MON3}, and I_{MON4}). The selection signal 315 is used to periodically select among the four current monitor output signals. The selected current monitor output signal 525 is received by an analog-to-digital converter (ADC) 530. For low duty cycle operation, down slop sample window is longer. The selected current monitor output signal 525 may be sampled at the rising edge of the system clock signal 218₁ and during PWM signal low window. The timing manager 510 is configured to control timing of the first four-input multiplexer 520. The timing manager 510 may be used to make sure that the ADC 530 has completed taking required number of sample for each current monitor output signal (e.g., I_{MON1}) before switching to next current monitor output signals (e.g., I_{MON2}) measurement. In some embodiments, the ADC 530 may be placed in a round-robin fashion. The ADC 530 collects M/N samples for each phase. In this example, for 4-phase phase multiplier (N=4), and the system clock signal 218₁ is 32 times (M=32), for example, of the incoming PWM signal PWMᵢₙ, the ADC 530 may collect 8 samples each time from a phase. In this depicted example, to sample, for example, 8 current values, the current monitor output signals I_{MONx} is sampled at downslope. In some embodiments, the current monitor output signals I_{MONx} may be sampled at upslope.

In this illustrative example, ISHARE 500 also includes a second multiplexer 540. The second four-input multiplexer 540 is also controlled by the selection signal 515 to selectively output the sampled values of each phase. For each phase, the sampled 8 current values will be received by a calculation circuit 550. The calculation circuit 550 calculates a moving average current I_{M-MONx} (e.g., I_{M-MON1}, I_{M-MON2}, I_{M-MON3}, I_{M-MON4}). For example, for the first current monitor output signal I_{MON1}, the ADC 530 collects 8 samples and sends the 8 samples to the calculation circuit 550 to generate a first moving average current I_{M-MON1}. For the second current monitor output signal I_{MON2}, the ADC 530 collects 8 samples and sends the 8 samples to the calculation circuit 550 to generate a second moving average current I_{M-MON2}. The calculated moving average current I_{M-MONx} (e.g., I_{M-MON1}, I_{M-MON2}, I_{M-MON3}, I_{M-MON4}) are received by a comparator circuit 560. As I_{MON1} is selected as the master current monitor output signal feeding backing directly to the PWM controller 125, the first moving average current I_{M-MON1} is used as a reference by a comparator system 560 to calculate a corresponding current different. The calculated current different may be used to adjust the duty cycle of the N-1 PWM signals (e.g., PWM₂, PWM₃, PWM₄). In some embodiments, as an ADC (e.g., the ADC 530) has converted analog data into digital data, a microcontroller or a state machine may be used to process the digital data. Thus, in digital domain, the second multiplexer 540 may be omitted. The digital data may also be synchronized with the system clock signal 210 for an accurate computation.

For example, I_{M-MON1} and I_{M-MON2} are received by a second comparator 560₂. The second comparator 560₂ calculates the difference between the I_{M-MON1} and I_{M-MON2}. The calculated difference 505₂ is received by the PWM signal generator 220b to fine tune the duty cycle of the PWM₂. A third comparator 560₃ calculates the difference 505₃ between the I_{M-MON3}. The calculated difference 505₃ may be used to fine tune the duty cycle of the PWM₃. A fourth comparator 560₄ calculates the difference 505₄ between the I_{M-MON1} and I_{M-MON4}. The calculated difference 505₄ may be used to fine tune the duty cycle of the PWM₄.

In some embodiments, the moving average current may be calculated in other ways. For example, to generate a first moving average current I_{M-MON1}, instead of using all 8 samples of the first phase current monitor output signal I_{MON1}, the calculation circuit 550 may be configured to pick the first two samples of the fourth phase current monitor output signal I_{MON1}, and pick the last six samples of the first phase current monitor output signal I_{MON1} to generate a first moving average current I_{M-MON1}. In some embodiments, the calculation circuit 550 may be configured to pick the first two samples of a previous first phase current monitor output signal I_{MON1}′ and pick the last six samples of the current first phase current monitor output signal I_{MON1} to generate a first moving average current I_{M-MON1}. When IMON signal from two switching cycles are used, inductor current move pattern may be studied. When deviation is high, it may be a result of a transient event. An algorithm may differentiate if moving average change is during steady state or during transient. Thus, system instability may be avoided.

FIG. 5C depicts exemplary timing diagram of a system clock signal, generated pulse-width-modulated (PWM) signals and phase currents. In this depicted example, the frequency of the system clock signal 218₁ is 32 times the frequency f_{sw} of the incoming PWM signal PWMᵢₙ. The generated PWM₁, PWM₂, PWM₃, and PWM₄ have the same frequency with the incoming PWM signal PWMᵢₙ.

Each of the phase current monitor output signals I_{MON1}, I_{MON2}, I_{MON3}, I_{MON4} generated by a corresponding SPS (e.g., SPS₁, SPS₂, SPS₃, SPS₄) has an upslope and a downslope. The upslope happens at the rising edge of a corresponding PWM signal, and the downslope happens at the falling edge of the corresponding PWM signal. Each phase current monitor output signals I_{MON1}, I_{MON2}, I_{MON3}, I_{MON4} will be sampled at the rising edge of the system clock signal 218₁ at the downslope of the phase current monitor output signal to obtain 8 samples. The sampled value may be used to generate the moving average current I_{M-MONx} (e.g., I_{M-MON1}, I_{M-MON2}, I_{M-MON3}, I_{M-MON4}).

FIG. 6 depicts a flow chart of an exemplary method to adjust duty cycles of the generated PWM signals to balance phase currents. The relationships between moving average current (e.g., I_{M-MON1}) of a master current monitor output signal (e.g., I_{MON1}) and a moving average current (e.g., I_{M-MON2}, I_{M-MON2}, I_{M-MON2}) of slave current monitor output signal (e.g., I_{MON2}, I_{MON3}, I_{MON4}) are monitored by a state machine (e.g., in the delay controller 245) to dynamically adjust the duty cycle of the slave PWM signal (e.g., PWM₂, PWM₃, PWM₄).

In this depicted example, a method 600 is discussed to fine tune duty cycle of the second PWM signal PWM₂. The first phase current monitor output signal I_{MON1} has been selected as the master signal to send back to the PWM controller 125. The moving average current I_{M-MON1} of the first phase current monitor output signal I_{MON1} has been calculated and the moving average current I_{M-MON2} of the second phase current monitor output signal I_{MON2} has also been calculated, for example, by the calculation circuit 550. A comparator system (e.g., the comparator system 560) calculates the difference (e.g., difference 505₂) between the I_{M-MON1} and I_{M-MON2}. A state machine of the delay controller 245 may be used to change the duty cycle of the second PWM signal PWM₂ based on the 505₂.

At 605, the state machine decides whether I_{M-MON1} equals I_{M-MON2} (e.g., whether difference 505₂ equals 0). If I_{M-MON1}=I_{M-MON2}, then, at 610, the state machine does nothing to the duty cycle (e.g., pulse width) of the second PWM signal PWM₂.

If I_{M-MON1} is not equal to I_{M-MON2}, then, at 615, the state machine decides whether I_{M-MON1} is greater than I_{M-MON2}. If I_{M-MON1} is greater than I_{M-MON2}, then, at 620, the state machine increases the duty cycle (e.g., pulse width) of the second PWM signal PWM₂. For example, the state machine may add a fine-tuning delay to the delay timer in the delay controller.

If I_{M-MON1} is less than I_{M-MON2}, then, at 625, the state machine decreases the duty cycle (e.g., pulse width) of the second PWM signal PWM₂. For example, the state machine may decrease a fine-tuning delay to the delay timer in the delay controller. The state machine keeps monitoring the relationship between I_{M-MON1} and I_{M-MON2} to dynamically adjust the duty cycle of the second PWM signal PWM₂. Thus, the pulse width of each slave PWM signal may be dynamically adjusted without losing the accuracy of the phase current monitor output signal I_{MON}.

Although various embodiments have been described with reference to the figures, other embodiments are possible. Some aspects of embodiments may be implemented as a computer system. For example, various implementations may include digital and/or analog circuitry, computer hardware, firmware, software, or combinations thereof. Apparatus elements can be implemented in a computer program product tangibly embodied in an information carrier, e.g., in a machine-readable storage device, for execution by a programmable processor; and methods can be performed by a programmable processor executing a program of instructions to perform functions of various embodiments by operating on input data and generating an output. Some embodiments may be implemented advantageously in one or more computer programs that are executable on a programmable system including at least one programmable processor coupled to receive data and instructions from, and to transmit data and instructions to, a data storage system, at least one input device, and/or at least one output device. A computer program is a set of instructions that can be used, directly or indirectly, in a computer to perform a certain activity or bring about a certain result. A computer program can be written in any form of programming language, including compiled or interpreted languages, and it can be deployed in any form, including as a stand-alone program or as a module, component, subroutine, or other unit suitable for use in a computing environment.

Suitable processors for the execution of a program of instructions include, by way of example and not limitation, both general and special purpose microprocessors, which may include a single processor or one of multiple processors of any kind of computer. Generally, a processor will receive instructions and data from a read-only memory or a random-access memory or both. The essential elements of a computer are a processor for executing instructions and one or more memories for storing instructions and data.

In various embodiments, a computer system may include non-transitory memory. The memory may be connected to the one or more processors , which may be configured for storing data and computer readable instructions, including processor executable program instructions. The data and computer readable instructions may be accessible to the one or more processors. The processor executable program instructions, when executed by the one or more processors, may cause the one or more processors to perform various operations.

Various examples of modules may be implemented using circuitry, including various electronic hardware. By way of example and not limitation, the hardware may include transistors, resistors, capacitors, switches, integrated circuits and/or other modules. In various examples, the modules may include analog and/or digital logic, discrete components, traces and/or memory circuits fabricated on a silicon substrate including various integrated circuits (e.g., FPGAs, ASICs). In some embodiments, the module(s) may involve execution of preprogrammed instructions and/or software executed by a processor. For example, various modules may involve both hardware and software.

In one exemplary aspect, a system includes a pulse-width-modulated (WPM) controller configured to generate an incoming PWM signal PWMᵢₙ in response to an output voltage signal and/or an output current signal for supply to a load. The system also includes a phase multiplier configured to generate, in response to the incoming PWM signal PWMᵢₙ, N-1 PWM signals (PWM₂, PWM₃, PWM₄) for N-1 power stages, the phase multiplier includes a delay module configured to receive the incoming PWM signal PWMᵢₙ and copy a pulse width W of the incoming PWM signal PWMᵢₙ. The phase multiplier also includes N-1 slices (2^{nd} slice, . . . , N^{th} slice) of PWM logic circuits configured to receive the pulse width W and a clock signal to generate N-1 PWM signals (PWM₂, PWMₙ). Each i^{th} slice of the N-1 slices of the PWM logic circuits includes a phase shifter, a delay controller, and a latch. The phase shifter is configured to generate a phase-shifted clock signal with a predetermined degree, the predetermined degree equals (i-1)*360/N, 2≤i≤N. The delay controller is configured to delay the pulse width W in response to the phase-shifted clock signal. The latch is configured to generate an i^{th} PWM signal in response to the phase-shifted clock signal and an output signal of the delay controller.

In some embodiments, the delay module may include a delay-locked-loop (DLL). In some embodiments, the PWM controller may be further configured to generate a sync clock signal associated with the PWMᵢₙ signal to be received by the phase multiplier. In some embodiments, the latch further comprises a set-reset (SR) latch, with a set input coupled to receive the phase-shifted clock signal, and a reset input coupled to receive the output signal of the delay controller. A rising edge of the output signal may happen at a time period of W after a rising edge of the phase-shifted clock signal.

In some embodiments, the system may also include N power stages, each of the N power stages may have an output coupled to supply a common output node, and N-1 of the N power stages coupled to a corresponding one of the N-1 slices of PWM logic circuits. Each of the N-1 power stages may be configured to operate according to a duty cycle and phase of a corresponding one of the N-1 PWM signals (PWM₂, . . . , PWMₙ). In some embodiments, one of the N power stages may be coupled to receive the incoming PWM signal PWMᵢₙ. In some embodiments, the phase multiplier may also include a frequency synthesizer configured to generate the clock signal in response to receiving a sync clock signal. The clock signal may have a frequency that is 32 times a frequency of the incoming PWM signal PWMᵢₙ. The sync clock signal may have the same frequency as the incoming PWM signal PWMᵢₙ. In some embodiments, the N-1 slices (2^{nd} slice, . . . , N^{th} slice) of the PWM logic circuits may be further configured to receive the phase-shifted clock signal to generate the N-1 PWM signals (PWM₂, . . . , PWMₙ).

In some embodiments, the system may also include N power stages configure to receive the N PWM signals and correspondingly generate N current monitor output signals. A first current monitor output signal (IMON₁) of a first power stage (SPS1) may be received by the PWM controller, and each of the (N-1) slices of the PWM logic circuits may also include a phase current control circuit (ISHARE) coupled to receive the N current monitor output signals from the N power stages. The ISHARE may be configured to generate a corresponding fine-tuning signal (505ᵢ) in response to the N current monitor output signals to adjust a pulse width of a corresponding one of the N-1 PWM signals. In some embodiments, the ISHARE may include a N-input selection circuit configured to receive the N current monitor output signals from the N smart power stages. A selection signal may be configured to select one of the N current monitor output signals at a frequency that is N times a frequency of the incoming PWM signal PWMᵢₙ. The ISHARE may also include an analog-to-digital converter configured to sample and convert each of the N current monitor output signal selected. The ISHARE may also include a calculation circuit configured to generate N average current values corresponding to the N current monitor output signals being sampled and converted. The ISHARE may also include a comparator system configured to receive the N average current values and generate N-1 current differences between one of the N average current values and each one of the other N-1 average current values. Each of the N-1 current differences may be received by a corresponding delay controller as the corresponding fine-tuning signal to adjust the pulse width of the corresponding one of the N-1 PWM signals.

In another exemplary aspect, an integrated circuit, configured to generate N-1 pulse-width-modulated (PWM) signals, includes (1) a delay module configured to receive an incoming PWM signal PWMᵢₙ and copy a pulse width W of the incoming PWM signal PWMᵢₙ, and, (2) N-1 slices (2^{nd} slice, . . . , N^{th} slice) of PWM logic circuits configured to receive the pulse width W and a clock signal to generate N-1 PWM signals (PWM₂, PWMₙ). Each i^{th} slice of the N-1 slices of the PWM logic circuits includes (1) a delay controller configured to delay the pulse width W in response to the clock signal, and, (2) a latch configured to generate an i^{th} PWM signal in response to the clock signal and an output signal of the delay controller.

In some embodiments, each i^{th} slice of the N-1 slices of the PWM logic circuits may also include a phase shifter configured to receive a system clock signal and generate the clock signal with a predetermined degree to generate the clock signal, the predetermined degree may equal (i-1)*360/N, 2≤i≤N. In some embodiments, the integrated circuit may also include a frequency synthesizer configured to receive a sync clock signal and generate the system clock signal, the system clock signal may have a frequency that is 32 times a frequency of the incoming PWM signal PWMᵢₙ. In some embodiments, the latch further may include a set-reset (SR) latch, with a set input coupled to receive the clock signal, and a reset input coupled to receive the output signal of the delay controller, a rising edge of the output signal may happen at a time period of W after a rising edge of the clock signal. In some embodiments, the delay module may include a delay-locked-loop (DLL).

In another exemplary aspect, a method to generate N-1 pulse-width-modulated (PWM) signals includes (1) receiving, by a delay module, an incoming PWM signal PWMᵢₙ and copying a pulse width W of the incoming PWM signal PWMᵢₙ, (2) receiving, by N-1 slices (2^{nd} slice, . . . , N^{th} slice) of PWM logic circuits, the pulse width W and a clock signal to generate N-1 PWM signals (PWM₂, PWMₙ), (3) delaying, by a corresponding delay controller of each of the N-1 slices of PWM logic circuits, the pulse width W in response to the clock signal, and, (4) generating, by a latch of each of the N-1 slices of PWM logic circuits, an i^{th} PWM signal in response to the clock signal and an output signal of the delay controller.

In some embodiments, the method may also include receiving a system clock signal and generating, by a phase shifter, a phase-shifted clock signal with a predetermined degree to generate the clock signal, the predetermined degree may equal (i-1)*360/N, 2≤i≤N. In some embodiments, the method may also include receiving a sync clock signal and generating, by a frequency synthesizer, the system clock signal, the system clock signal has a frequency that is 32 times a frequency of the incoming PWM signal PWMᵢₙ, the sync clock signal may have the same frequency with the incoming PWM signal PWMᵢₙ. In some embodiments, the latch may also include a set-reset (SR) latch, with a set input coupled to receive the clock signal, and a reset input coupled to receive the output signal of the delay controller, a rising edge of the output signal may happen at a time period of W after a rising edge of the clock signal. In some embodiments, the delay module may include a delay-locked-loop (DLL).

A number of implementations have been described. Nevertheless, it will be understood that various modification may be made. For example, advantageous results may be achieved if the steps of the disclosed techniques were performed in a different sequence, or if components of the disclosed systems were combined in a different manner, or if the components were supplemented with other components. Accordingly, other implementations are within the scope of the following claims.

1. A system, comprising:
a pulse-width-modulated (PWM) controller configured to generate an incoming PWM signal PWMᵢₙ in response to an output voltage signal and/or an output current signal for supply to a load;
a phase multiplier configured to generate, in response to the incoming PWM signal PWMᵢₙ, N-1 PWM signals for N-1 power stages, each of the N-1 PWM signals has the same frequency as the incoming PWM signal PWMᵢₙ, wherein the phase multiplier is further configured to adjust a duty cycle of each of the N-1 PWM signals in response to a corresponding fine-tuning signal, wherein the phase multiplier comprises:
a delay module configured to receive the incoming PWM signal PWMᵢₙ and copy a pulse width W of the incoming PWM signal PWMᵢₙ;
N-1 slices of PWM logic circuits configured to receive the pulse width W and a clock signal to generate N-1 PWM signals, wherein each i^{th} slice of the N-1 slices of the PWM logic circuits comprises:
a phase shifter configured to generate an i^{th} phase-shifted clock signal;
a delay controller configured to receive the pulse width and the i^{th} phase-shifted clock signal to generate an output signal; and,
a latch configured to generate an i^{th} PWM signal in response to the phase-shifted clock signal and the output signal such that the phase difference between the i^{th} PWM signal and incoming PWM signal PWMᵢₙ equals (i-1)*360/N, 2≤i≤N,
wherein the delay controller is further configured to update the output signal to adjust the duty cycle of the i^{th} PWM signal in response to a corresponding fine-tuning signal indicating a current difference between an i^{th} current monitor output signal generated by an i^{th} power stage and a reference current output signal generated by a reference power stage.

2. The system of claim 1, wherein the delay module comprises a delay-locked-loop (DLL).

3. The system of claim 1, wherein the PWM controller is further configured to generate a sync clock signal associated with the PWMᵢₙ signal to be received by the phase multiplier.

4. The system of claim 1, wherein the latch further comprises a set-reset (SR) latch, with a set input coupled to receive the phase-shifted clock signal, and a reset input coupled to receive the output signal of the delay controller, wherein a rising edge of the output signal happens at a time period of W after a rising edge of the phase-shifted clock signal.

5. The system of claim 1, further comprising N power stages, each of the N power stages having an output coupled to supply a common output node, and N-1 of the power stages coupled to a corresponding one of the N-1 slices of PWM logic circuits, wherein each of the N-1 power stages is configured to operate according to a duty cycle and phase of a corresponding one of the N-1 PWM signals.

6. The system of claim 5, wherein one of the N power stages is coupled to receive the incoming PWM signal PWMᵢₙ.

7. The system of claim 1, wherein the phase multiplier further comprises:
a frequency synthesizer configured to generate the clock signal in response to receiving a sync clock signal, wherein the clock signal has a frequency that is 32 times a frequency of the incoming PWM signal PWMᵢₙ.

8. The system of claim 7, wherein the N-1 slices of the PWM logic circuits are further configured to receive the phase-shifted clock signal to generate the N-1 PWM signals.

9. The system of claim 1, further comprising:
N power stages configure to receive N PWM signals and correspondingly generate N current monitor output signals, wherein the PWM controller is further configured to receive a first current monitor output signal of a first power stage as the reference current output signal, and each of the N-1 slices of the PWM logic circuits further comprises:
a phase current control circuit (ISHARE) coupled to receive the N current monitor output signals from the N power stages, wherein the ISHARE is configured to generate the corresponding fine-tuning signal.

10. The system of claim 9, wherein the ISHARE comprises:
a N-input selection circuit configured to receive the N current monitor output signals from the N power stages, wherein a selection signal is configured to select one of the N current monitor output signals at a frequency that is N times a frequency of the incoming PWM signal PWMᵢₙ;
an analog-to-digital converter configured to sample and convert each of the N current monitor output signals selected;
a calculation circuit configured to generate N average current values corresponding to the N current monitor output signals being sampled and converted; and,
a comparator system configured to receive the N average current values and generate N-1 current differences between one of the N average current values and each one of the other N-1 average current values, wherein each of the N-1 current differences is received by a corresponding delay controller as the corresponding fine-tuning signal to adjust the pulse width of the corresponding one of the N-1 PWM signals.

11. A phase multiplier configured to generate, in response to an incoming PWM signal PWMᵢₙ, N-1 PWM signals for N-1 power stages, each of the N-1 PWM signals has the same frequency as the incoming PWM signal PWM, wherein the phase multiplier is further configured to adjust a duty cycle of each of the N-1 PWM signals in response to a corresponding fine-tuning signal, the phase multiplier comprises:
N-1 slices of PWM logic circuits configured to receive the pulse width W and a system clock signal to generate N-1 PWM signals, wherein each i^{th} slice of the N-1 slices of the PWM logic circuits comprises:
a phase shifter configured to generate an i^{th} phase-shifted clock signal in response to the system clock signal;
a delay controller configured to receive a pulse width W of the PWMᵢₙ and the i^{th} phase-shifted clock signal to generate an output signal; and
a latch configured to generate an i^{th} PWM signal in response to the i^{th} phase-shifted clock signal and the output signal such that the phase difference between the i^{th} PWM signal and the incoming PWM signal PWMᵢₙ equals (i-1)*360/N, 2≤i≤N,
wherein the delay controller is further configured to update the output signal to adjust the duty cycle of the i^{th} PWM signal in response to a fine-tuning signal indicating a current difference between an i^{th} current monitor output signal generated by an i^{th} power stage and a reference current output signal generated by a reference power stage.

12. (canceled)

13. The integrated circuit of claim 11, further comprising:
a frequency synthesizer configured to receive a sync clock signal and generate the system clock signal, wherein the system clock signal has a frequency that is 32 times a frequency of the incoming PWM signal PWMᵢₙ.

14. The integrated circuit of claim 11, wherein the latch further comprises a set-reset (SR) latch, with a set input coupled to receive the i^{th} phase-shifted clock signal, and a reset input coupled to receive the output signal of the delay controller, wherein a falling edge of the output signal happens at a time period of W after a rising edge of the i^{th} phase-shifted clock signal.

15. The integrated circuit of claim 11, wherein the delay module comprises a delay-locked-loop (DLL).

16. A method to generate N-1 pulse-width-modulated (PWM) signals, the method comprising:
receiving, by a delay module, an incoming PWM signal PWMᵢₙ and copying a pulse width W of the incoming PWM signal PWMᵢₙ;
receiving, by N-1 slices of PWM logic circuits, the pulse width W and a first clock signal to generate N-1 PWM signals, wherein generating an i^{th} PWM signal of the N-1 PWM signals comprising:
generating, by a phase shifter, an i^{th} phase-shifted clock signal in response to the first clock signal;
receiving, by a delay controller of an i^{th} PWM logic circuit of the N-1 slices of PWM logic circuits, the pulse width and the i^{th} phase-shifted clock signal to generate an output signal;
generating, by a latch of the i^{th} PWM logic circuit an i^{th} PWM signal in response to the phase-shifted clock signal and the output signal such that the phase difference between the i^{th} PWM signal and the incoming PWM signal PWMᵢₙ equals (i-1)*360/N, 2≤i≤N, wherein the i^{th} PWM signal has the same frequency as the incoming PWM signal PWMᵢₙ;
generating, by a phase current control circuit (ISHARE), a fine-tuning signal indicating a current difference between an i^{th} current monitor output signal generated by an i^{th} power stage and a reference current output signal generated by a reference power stage; and,
updating the output signal, by the corresponding delay controller of the i^{th} PWM logic circuit, to adjust a duty cycle of the i^{th} PWM signal in response to the corresponding fine-tuning signal.

17. (canceled)

18. The method of claim 16, further comprising:
receiving a sync clock signal and generating, by a frequency synthesizer, the system clock signal, wherein the system clock signal has a frequency that is 32 times a frequency of the incoming PWM signal PWMᵢₙ.

19. The method of claim 16, wherein the latch further comprises a set-reset (SR) latch, with a set input coupled to receive the i^{th} phase-shifted clock signal, and a reset input coupled to receive the output signal of the delay controller, wherein a falling edge of the output signal happens at a time period of W after a rising edge of the i^{th} phase-shifted clock signal.

20. The method of claim 16, wherein the delay module comprises a delay-locked-loop (DLL).
